(19) United States
(12) Patent Application Publication
(10) Pub. No.: US 2025/0126924 A1
(43) Pub. Date: Apr. 17, 2025

(54) SUBSTRATE PROCESSING APPARATUS INCLUDING LIGHT RECEIVING DEVICE AND CALIBRATION METHOD OF LIGHT RECEIVING DEVICE

(71) Applicant: ASM IP Holding B.V., Almere (NL)

(72) Inventor: Kazuhiro Nishiwaki, Tokyo (JP)

(21) Appl. No.: 19/001,665

(22) Filed: Dec. 26, 2024

Related U.S. Application Data
(62) Division of application No. 17/172,082, filed on Feb. 10, 2021, now Pat. No. 12,218,269.
(60) Provisional application No. 62/976,311, filed on Feb. 13, 2020.

(51) Int. Cl. H10F 71/00; G01J 1/42; G01N 21/27; H01J 37/32

(52) U.S. Cl. CPC H10F 71/137; G01J 1/42; G01N 21/274; H01J 37/32715; H01J 37/32972; H10F 71/139; G01J 2001/4247

(57) ABSTRACT

Examples of a substrate processing apparatus includes a chamber configured to contain a stage, a light receiving device configured to receive light inside the chamber, and a substrate transfer apparatus that includes a shaft and a rotation arm configured to rotate with rotation of the shaft and is configured to supply a plurality of light beams having different amounts of light to the light receiving device.

### CROSS-REFERENCE TO RELATED APPLICATIONS

This application is a divisional of, and claims priority to, U.S. patent application Ser. No. 17/172,082 filed Feb. 10, 2021 titled SUBSTRATE PROCESSING APPARATUS INCLUDING LIGHT RECEIVING DEVICE AND CALIBRATION METHOD OF LIGHT RECEIVING DEVICE, which claims the benefit of and priority to U.S. Provisional Application No. 62/976,311, filed on Feb. 13, 2020 in the United States Patent and Trademark Office, the disclosure of which is incorporated herein in its entirety by reference.

### TECHNICAL FIELD

Examples are described which relate to a substrate processing apparatus and a calibration method.

### BACKGROUND

For example, in an ALD process, plasma emission may be detected by a Si photodiode sensor to monitor synchronism between a command output of RF-ON and plasma emission or to monitor a plasma emission intensity. However, since no defense system for diagnosing a state of the photodiode sensor exists and an individual difference in the output of the photodiode sensor exists, a level based on the output value of the photodiode sensor cannot be determined.

### SUMMARY

Some examples described herein may address the above-described problems. Some examples described herein may provide a substrate processing apparatus and a calibration method of a light receiving device which are capable of determining a level of the output of the light receiving device.

In some examples, a substrate processing apparatus includes a chamber configured to contain a stage, a light receiving device configured to receive light inside the chamber, and a substrate transfer apparatus that includes a shaft and a rotation arm configured to rotate with rotation of the shaft and is configured to supply a plurality of light beams having different amounts of light to the light receiving device.

### BRIEF DESCRIPTION OF THE DRAWINGS

FIG. 1 illustrates a configuration example of a substrate processing apparatus;

FIG. 2 illustrates an example of the characteristics of the light receiving device;

FIG. 3 shows a partial cross-sectional view of the substrate processing apparatus;

FIG. 4A is a cross-sectional view taken along line A-A in FIG. 3;

FIG. 4B is a cross-sectional view of a shaft according to another example;

FIG. 5 is a flowchart illustrating an example of the calibration method;

FIG. 6A shows an example of the outputs of the light receiving devices;

FIG. 6B shows an example of the outputs of the light receiving devices;

FIG. 6C shows an example of the outputs of the light receiving devices;

FIG. 7A shows the outputs of the plurality of light receiving devices before calibration;

FIG. 7B shows the outputs of the plurality of light receiving devices after calibration;

FIG. 8 illustrates that light is supplied from a rotation arm to a light receiving device;

FIG. 9 shows an light emitting wafer; and

FIG. 10 illustrates a dual chamber module and a light emitting wafer.

### DETAILED DESCRIPTION

A substrate processing apparatus and a calibration method will be described with reference to the drawings. The same or corresponding components are denoted by the same reference numerals and description thereof may not be repeated.

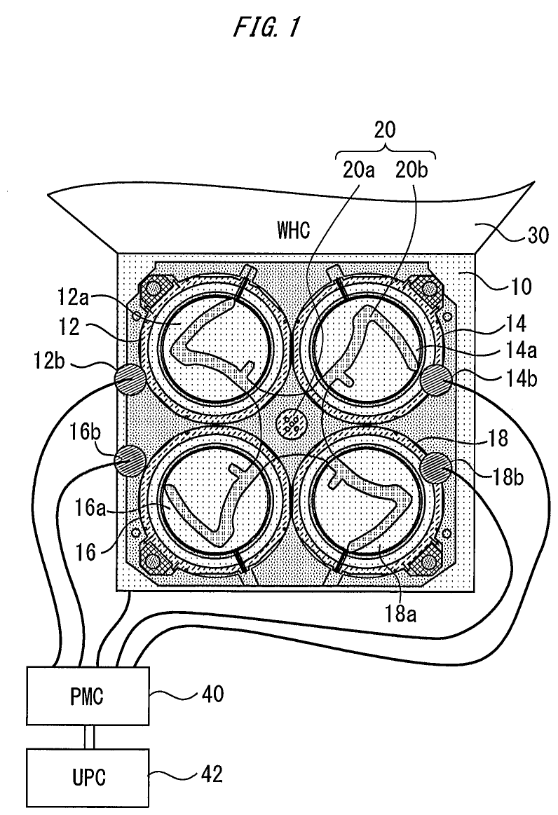

FIG. 1 is a diagram illustrating a configuration example of a substrate processing apparatus. The substrate processing apparatus forms a quad chamber module (QCM) in which four chamber modules are provided in a chamber 10. The number of chamber modules is not particularly limited. According to an example, four chambers 12, 14, 16, and 18 are provided in the chamber 10. The chambers 12, 14, 16, and 18 can be provided as reactor chambers, for example. According to an example, each of the chambers is a plasma processing apparatus.

Stages 12a, 14a, 16a, and 18a are provided inside the chambers 12, 14, 16, and 18, respectively. These stages are, for example, susceptors. Light receiving devices 12b, 14b, 16b, and 18b are provided outside the chamber 12, 14, 16, and 18, respectively. According to an example, a plurality of light receiving devices are provided in one-to-one correspondence with a plurality of chambers. For example, the light receiving devices 12b, 14b, 16b, and 18b can receive light inside the chambers 12, 14, 16, and 18 through viewports of the chambers, respectively. According to an example, the light receiving devices 12b, 14b, 16b, and 18b are silicon photodiode sensors.

A substrate transfer apparatus 20 is provided in the chamber 10. According to an example, the substrate transfer apparatus 20 includes a shaft 20a and rotation arms 20b that rotate with the rotation of the shaft 20a. In the example of FIG. 1, four rotation arms 20b fixed to the shaft 20a rotate with the rotation of the shaft 20a extending in a direction perpendicular to the paper. A substrate can be moved between the stages by the substrate transfer apparatus 20.

A wafer handling chamber (WHC) 30 is connected to the chamber 10. A wafer transfer arm present in the WHC 30 provides the substrate on the stages 12a and 14a or removes the substrate from the stages 12a and 14a.

According to an example, a process module controller (PMC) 40 receives outputs of the light receiving devices 12b, 14b, 16b, and 18b, controls the light receiving devices 12b, 14b, 16b, and 18b, and controls the substrate transfer apparatus 20. In this example, a unique platform controller (UPC) 42 instructs the PMC 40 to operate each of the modules, and the PMC 40 controls each of the modules based on the instruction. According to another example, each of the modules can be controlled by a controller different from the UPC 42 and the PMC 40.

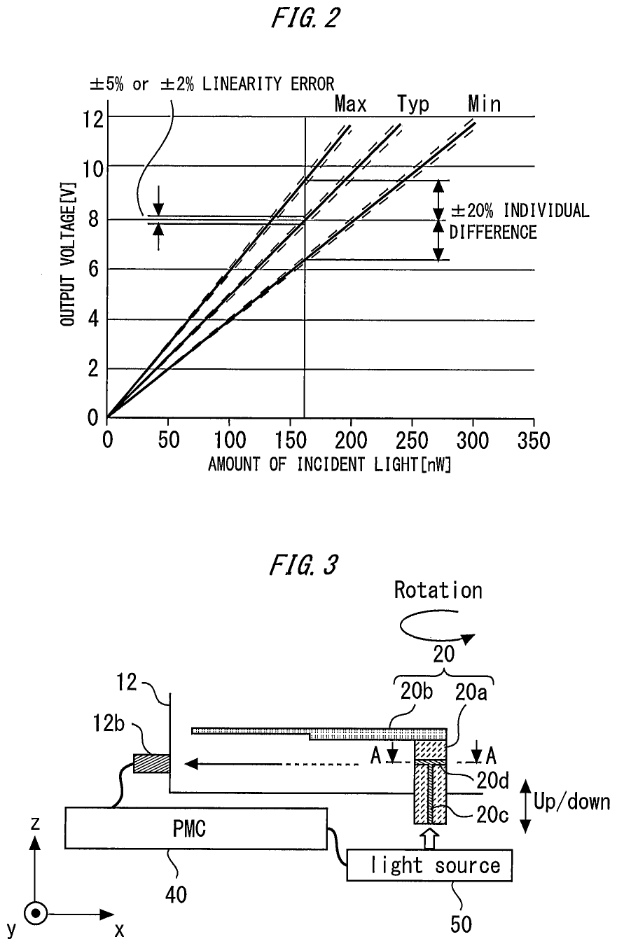

FIG. 2 is a diagram illustrating an example of a relation between an amount of light incident on the light receiving device and an output voltage. According to this example, when the amount of incident light is 160 nW, the output of the light receiving device varies by about 20% due to individual differences. In addition, a linearity error of one light receiving device also occurs about 5%. Accordingly, when the light receiving devices 12b, 14b, 16b, and 18b are used without taking a measure, the outputs thereof can hardly be used for level determination or used for understanding differences between the chambers.

FIG. 3 is a partial cross-sectional view of the substrate processing apparatus in FIG. 1. The shaft 20a is a rotating shaft extending long in a z-direction. The substrate transfer apparatus 20 can be moved in a positive z-direction and a negative z-direction by a driving mechanism provided inside or outside the chamber 10. The shaft 20a is formed with a hole 20c and a hole 20d, for example. The hole 20c is a hole extending in the shaft 20a in substantially parallel with a z-axis. The hole 20d is a hole extending in the shaft 20a so as to be substantially perpendicular to the z-axis and coupled to the hole 20c. According to an example, a plurality of holes 20d can be provided on a side face of the shaft 20a.

In this example, a light source 50 is provided outside the chamber 12. The light source 50 may be provided inside the chamber 10. However, when the light source 50 is provided outside the chamber 12, maintenance of the light source 50 is facilitated. The light source 50 is turned on and off under the control of the PMC 40, for example. The light source 50 supplies light to the holes 20c and 20d. According to an example, the light source 50 is connected to the shaft 20a by an optical fiber, and thus the light can be supplied to the holes 20c and 20d. According to another example, a part of the shaft is provided with a cavity through which the light source can be inserted and removed, the light source is provided in the cavity, and thus the light can also be supplied to the holes 20c and 20d. According to further another example, the light source can be provided at an arbitrary position.

When the light source 50 is turned on, the light is incident on the light receiving devices through the holes 20c and 20d. The light can be incident on the light receiving device 12b, 14b, 16b, and 18b by light emission of the light source 50 with the rotation of the shaft 20a or repetition of the rotation of the shaft 20a and the light emission of the light source 50.

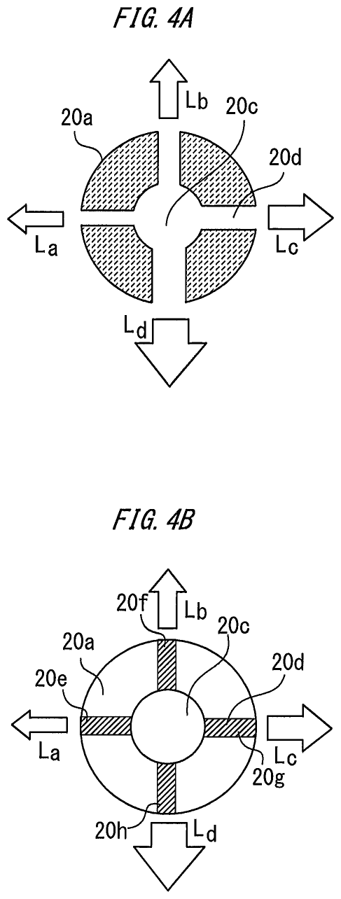

FIG. 4A is a cross-sectional view taken along line A-A in FIG. 3. The side face of the shaft 20a is provided with a plurality of holes 20d through which the light of the light source passes. In this example, the plurality of holes 20d having different cross-sectional areas are provided. Light having a high light intensity is emitted from the hole having a large cross-sectional area, and light having a low light intensity is emitted from the hole having a small cross-sectional area. In FIG. 4A, light La, Lb, Lc, and Ld emitted from four holes 20d are indicated by arrows. A thickness of the arrow indicates magnitude of the light intensity. Since the cross-sectional area of the light path of the light La, the cross-sectional area of the light path of the light Lb, the cross-sectional area of the light path of the light Lc, and the cross-sectional area of the light path of the light Ld increase in this order, the light intensity satisfies a relation of light La<light Lb<light Lc<light Ld.

FIG. 4B is a cross-sectional view of a shaft according to another example. In this example, four holes 20d have substantially an identical cross-sectional area. The four holes 20d are provided with light transmitting materials 20e, 20f, 20g, and 20h which are different in light transmissivity from each other. The light transmitting materials 20e, 20f, 20g, and 20h are, for example, ceramics. The light transmitting material 20e has the lowest light transmissivity, followed in order by light transmitting materials 20f, 20g, and 20h. As a result, the light intensity satisfies a relation of light La<light Lb<light Lc<light Ld.

In the examples of FIGS. 4A and 4B, the light emitted from one light source passes through the inside of the shaft 20a and is divided into a plurality of light beams which are different in light intensity from each other, and the divided light are supplied to the light receiving devices. By adjustment of the shape or material of the shaft in a different manner from that in FIGS. 4A and 4B, a plurality of light beams having different light intensities can be supplied.

According to an example, a calibration method of the plurality of light receiving devices includes allowing light to be incident on the plurality of light receiving devices from one light source and subsequently performing a system calibration such that outputs of the plurality of light receiving devices are identical to each other when the plurality of light receiving devices receive light having the identical amount of light from one light source. The system calibration can also be referred to as scaling.

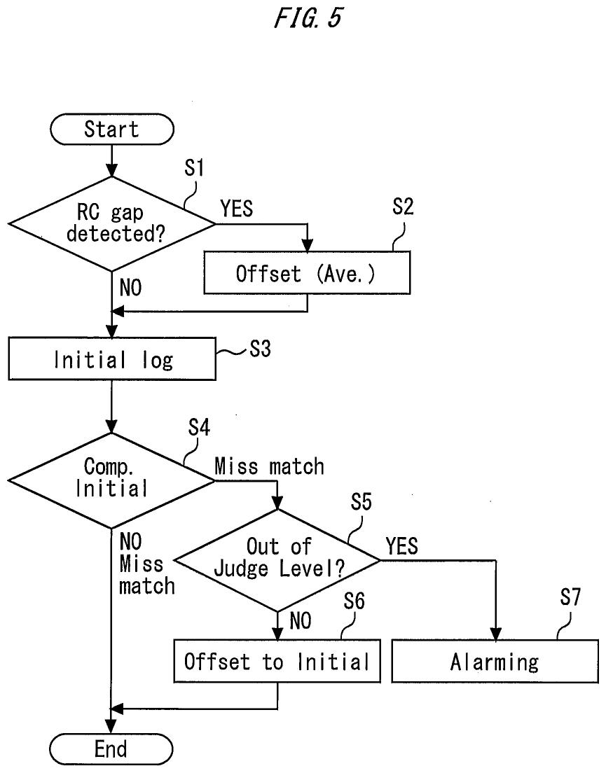

FIG. 5 is a flowchart illustrating an example of the calibration method of the light receiving devices. First, in step S1, the plurality of light beams, which are different in amount of light or light intensity from each other, are incident on the light receiving devices 12b, 14b, 16b, and 18b from the side face of the shaft 20a in the manner described above. According to an example, light is supplied with the rotation of the shaft 20a in a continuous or intermittent way, and thus a plurality of light beams having different light intensities are sequentially incident on all of the light receiving devices. For example, the light La, Lb, Lc, and Ld are sequentially incident on the light receiving device 12b, the light La, Lb, Lc, and Ld are sequentially incident on the light receiving device 14b, the light La, Lb, Lc, and Ld are sequentially incident on the light receiving device 16b, and the light La, Lb, Lc, and Ld are sequentially incident on the light receiving device 18b.

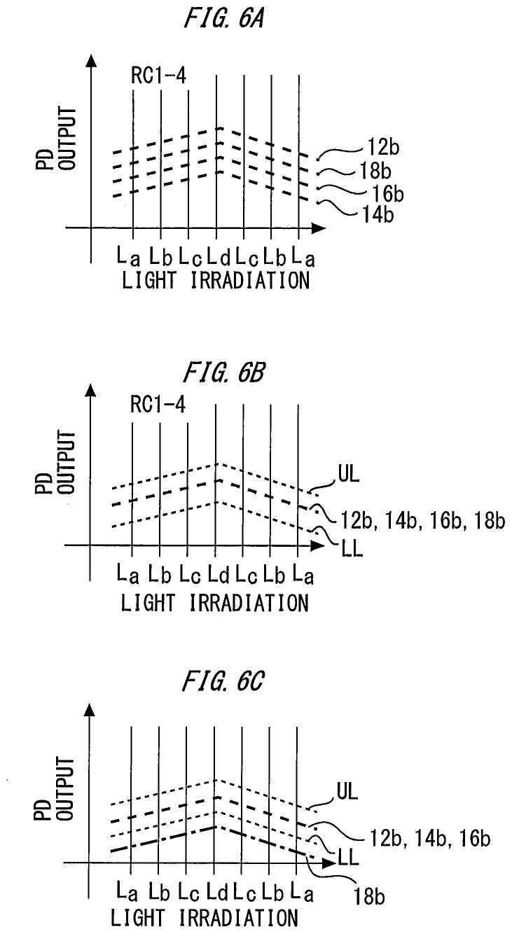

Then, as described above, the outputs of the light receiving devices vary due to the error of the light receiving devices even though the light La, Lb, Lc, and Ld having the identical light intensity are incident on all of the light receiving devices. FIG. 6A is a diagram illustrating an example of the outputs of the light receiving device 12b, 14b, 16b, and 18b obtained in step S1. As is clear from this drawing, variation occurs in the outputs with respect to the identical light input due to characteristic variations of the light receiving devices.

When such output variation is detected in step S1, the process proceeds to step S2. In step S2, the controllers exemplified by the PMC 40 and the UPC 42 perform system calibration such that the outputs of the plurality of light receiving devices receiving the light having the identical amount of light from one light source are identical to each other. FIG. 6B is a diagram illustrating that the outputs of the plurality of light receiving devices are made identical by the system calibration. By the calibration in step S2, the outputs of the plurality of light receiving devices receiving the light with the identical light intensity can be made identical.

On the other hand, when the relation illustrated in FIG. 6B is obtained in step S1, for example, such a system calibration is naturally unnecessary.

Subsequently, a relation between the light inputs and the outputs of the light receiving devices through the calibration or without the calibration is stored as an initial log in, for example, the controller or an external storage device in step S3.

Thereafter, for example, after a certain period of time has elapsed since the processing of the substrate using the substrate processing apparatus or the transfer of the substrate is performed, the process proceeds to step S4. In step S4, the light having the amount of light identical to that at the time of the system calibration is incident on the plurality of light receiving devices from one light source. For example, the light La, Lb, Lc, and Ld are sequentially received by all of the light receiving devices. Then, it is confirmed whether the outputs of the plurality of light receiving devices are maintained to be identical to each other. Such a confirmation can be performed by comparison between the obtained outputs of the light receiving devices and the initial log stored in step S3.

When at least one of the outputs of the light receiving devices obtained in step S4 does not match the initial log, the process proceeds to step S5. FIG. 6C is a diagram illustrating an example of such a miss match. In this example, when the light having the amount of light identical to that at the time of the system calibration is received, the outputs of the light receiving devices 12b, 14b, and 16b match the initial log, but the output of the light receiving device 18b does not match the initial log. The light receiving device having the output not match the initial log is referred to as an output variation device. When the output variation device is present, it is determined whether the difference between the output of the output variation device and the initial log exceeds a threshold. In other words, it is determined whether the output change amount of the output variation device exceeds the threshold. For example, it is determined in the example of FIG. 6C whether the output of the output variation device is in a range between an upper limit value UL and a lower limit value LL. When the output of the output variation device is in the range between the upper limit value UL and the lower limit value LL, the process proceeds to step S6, and the system is re-calibrated such that the outputs of the plurality of light receiving devices are identical to each other. For example, calibration is performed such that the output of the output variation device matches the initial log.

On the other hand, when the output change amount of the output variation device exceeds the threshold, an alarm is issued in step S7. In the example of FIG. 6C, since the output of the light receiving device 18b, which is an output variation device, is lower than the lower limit value LL, an alarm is issued.

When the latest output values of the plurality of light receiving devices match the initial log in step S4, the process ends without re-calibration. Steps S4 to S7 can be performed periodically or after the end of a specific process. The confirmation of the necessity of periodical re-calibration or the necessity of alarming makes it possible to prevent the outputs of the light receiving devices from changing with respect to the constant input with the lapse of time. The calibration process and the re-calibration process can be performed by automatic processing of the controller.

By the calibration of the outputs of the plurality of light receiving devices in this manner, the output levels of the light receiving devices can be determined, for example, in substrate processing involving plasma emission. For example, it is possible to investigate whether substantially identical plasma is generated in a plurality of chambers, and to investigate whether plasma having an emission intensity in a predetermined range is generated in the plurality of chambers. When plasma having an intended emission intensity is not generated in a specific chamber, processing conditions of the chamber can be changed in order to realize the plasma having the intended emission intensity. As an example, high-frequency power is adjusted or a gas supplied to the chamber can be adjusted. According to another example, the outputs of the light receiving devices can be fed back to the process condition of the substrate.

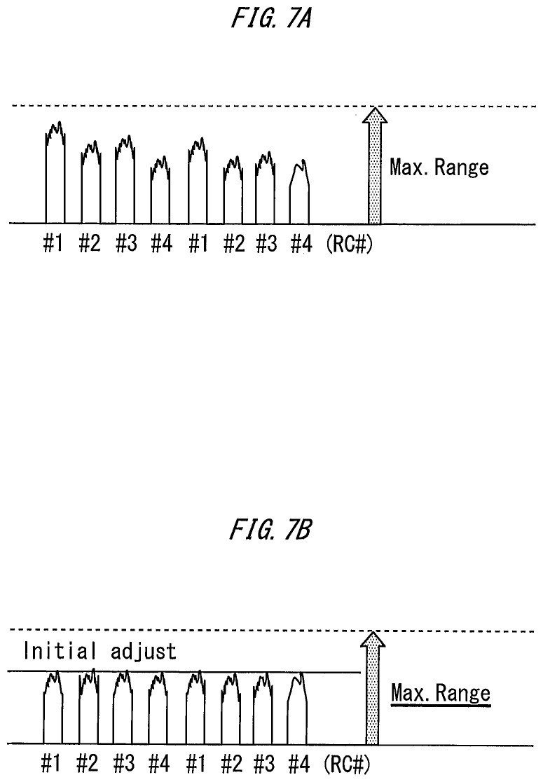

FIGS. 7A and 7B are diagrams simply illustrating that the outputs of the plurality of light receiving devices are unified by calibration or re-calibration. A symbol RC# represents a reactor chamber number.

In the example of FIG. 3, the light of the light source 50 is divided into a plurality of light beams by the shaft 20a. However, according to another example, the light of the light source is divided at an arbitrary portion of the substrate transfer apparatus, and a plurality of light beams having different light intensities can be supplied to the light receiving devices. For example, the light of the light source may be supplied from the rotation arm to the light receiving devices.

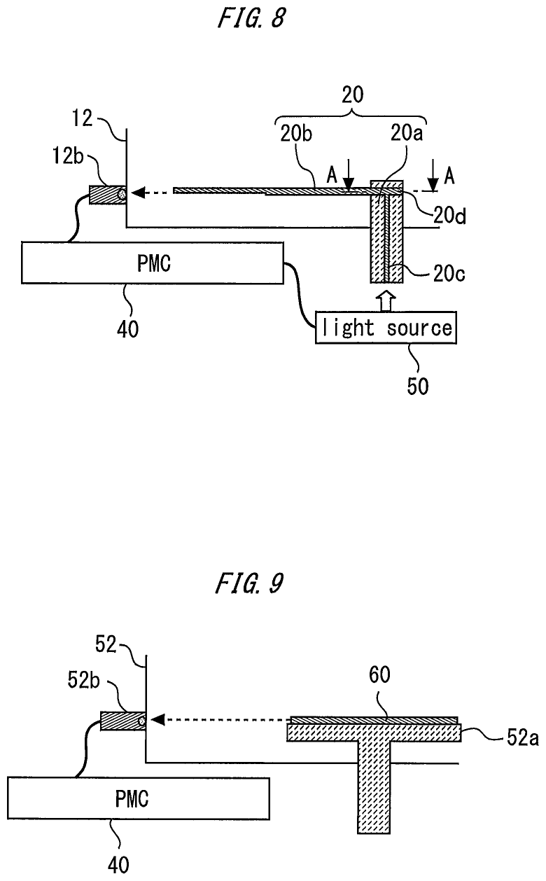

FIG. 8 is a diagram illustrating that light is supplied from a rotation arm to a light receiving device. A plurality of rotation arms 20b are formed of a light transmitting material that transmits light. As an example of the light transmitting material, quartz or translucent ceramic may be used.

A shaft 20a is provided with holes 20c extending in a direction substantially parallel to the z-axis and a plurality of holes 20d extending from the side face of the shaft 20a to the hole 20c. The plurality of holes 20d provided on the side face of the shaft 20a can be holes having different cross-sectional areas as illustrated in FIG. 4A. According to another example, the plurality of holes 20d can also be provided with light transmitting materials which are different in light transmissivity from each other as illustrated in FIG. 4B.

The plurality of rotation arms 20b can be provided in one-to-one correspondence with the plurality of holes 20d. For example, one rotation arm is provided adjacent to the outlet of one hole 20d. The light from the light source passes through the holes 20c and the plurality of holes 20d, the plurality of rotation arms emit light, and thus the light is supplied to the plurality of light receiving devices.

According to another example, light for calibration or re-calibration can be supplied from a light emitting wafer to light receiving devices. FIG. 9 is a cross-sectional view of a light emitting wafer 60 and other parts. According to an example, the light emitting wafer 60 includes a fluorescent material, includes a battery and a light emitting device, or includes an LED, thereby emitting light. According to another example, the light emitting wafer 60 may employ an LED-mounted teaching wafer used in an Auto teaching system presented by cyber optics Corp. According to an example, the light emitting wafer 60 supplies a plurality of light beams having different amounts of light to the plurality of light receiving devices. The light emitting wafer 60 can be provided to or taken out of the chamber by a transfer system used for a product wafer.

The light emitting wafer 60 is placed on a stage in a certain chamber, and supplies light to a light receiving device that monitors the inside of the chamber. Then, the light emitting wafer 60 is placed on a stage in another chamber, and supplies light to a light receiving device that monitors the inside of the chamber. Thus, the movement of the light emitting wafer and the supply of the reference light to the light receiving devices are repeatedly performed in this manner, the reference light is supplied from one light emitting wafer 60 to all of the light receiving devices.

According to another example, the light emitting wafer 60 is placed on the rotation arm, and the light is incident on the plurality of light receiving devices from the light emitting wafer using the rotation of the rotation arm.

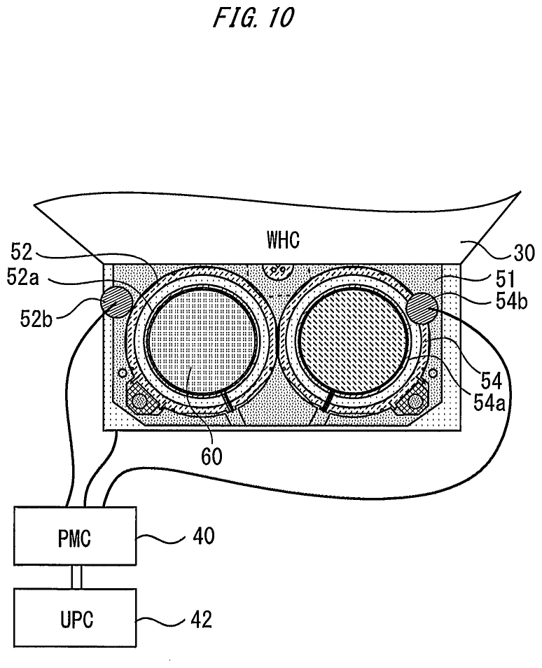

FIG. 10 is a diagram illustrating a dual chamber module (DCM) 51 and a light emitting wafer 60. In a case of the DCM 51, the light emitting wafer 60 is placed on a stage 52a in a chamber 52, and reference light is supplied from the light emitting wafer 60 to a light receiving device 52b. Further, the light emitting wafer 60 is placed on a stage 54a in a chamber 54, and reference light is supplied from the light emitting wafer 60 to a light receiving device 54b.

For example, the processing for calibration or re-calibration of the light receiving devices in FIG. 5 is identically applied to the case where the reference light is supplied from the substrate transfer apparatus to the light receiving device and the case where the reference light is supplied from the light emitting wafer to the light receiving devices.

1. A calibration method comprising in order of:
allowing light to be incident on a plurality of light receiving devices, which are provided in one-to-one correspondence with a plurality of chambers, from one light source; and
performing a system calibration such that outputs of the plurality of light receiving devices are identical to each other when the plurality of light receiving devices receive light having an identical amount of light from the one light source.

2. The calibration method according to claim 1, wherein the system calibration is performed by allowing a plurality of light beams having different light intensities to be sequentially incident on the plurality of light receiving devices.

3. The calibration method according to claim 1, wherein
the plurality of chambers include a QCM, and
the light is incident by supplying light from a substrate transfer apparatus including a shaft and a rotation arm while continuously or intermittently rotating the substrate transfer apparatus.

4. The calibration method according to claim 1, wherein
the plurality of chambers include a QCM, and
the light is incident by providing a light emitting wafer on a stage of the QCM.

5. The calibration method according to claim 1, wherein
the plurality of chambers include a DCM, and
the light is incident by providing a light emitting wafer on a stage of the DCM.

6. The calibration method according to claim 1, wherein each of the plurality of chambers is a plasma processing apparatus.

7. The calibration method according to claim 1, further comprising:
after the system calibration, allowing light having an amount of light identical to that at the time of the system calibration to be incident on the plurality of light receiving devices and confirming whether the outputs of the plurality of light receiving devices are maintained to be identical to each other.

8. The calibration method according to claim 7, further comprising, when an output variation device serving as a light receiving device not be maintained with an identical output is present in the confirming:
performing a system re-calibration such that the outputs of the plurality of light receiving devices are identical to each other when an output change amount of the output variation device does not exceed a threshold, and issuing an alarm when the output change amount of the output variation device exceeds the threshold.
